(19) United States
(12) Patent Application Publication
(10) Pub. No.: US 2011/0030794 A1
(43) Pub. Date: Feb. 10, 2011

(54) Apparatus And Method For Depositing A CIGS Layer

(76) Inventor: Edward Teng, Sunnyvale, CA (US)

Correspondence Address: INTELLECTUAL PROPERTY LAW GROUP LLP, 12 SOUTH FIRST STREET, SUITE 1205, SAN JOSE, CA, 95113, US

(21) Appl. No.: 12/853,254

(22) Filed: Aug. 9, 2010

Related U.S. Application Data
(60) Provisional application No. 61/273,840, filed on Aug. 10, 2009.

(51) Int. Cl. H01L 31/0256; H01L 31/0272; H01L 31/0336; C23C 14/24; C23C 14/34

(52) U.S. Cl. 136/262; 204/298.26; 204/298.13; 204/192.28; 204/192.11

(57) ABSTRACT

A method and apparatus for depositing a CIGS film and a buffer layer on to a flexible substrate. Deposition of the CIGS film occurs in monolayers due to rotation of the flexible substrate. A roll of substrate is placed on a loading roller within a flexible solar cell coating apparatus. A section of the substrate unwinds and advances around a rotating drum. The CIGS film is deposited as the section is rotated and heated. Deposition is a hybrid sputtering and evaporation process. Deposition continues until a predetermined thickness is met and the roll is completely coated. The buffer layer is then deposited on to the CIGS film. The deposition of the CIGS film utilizes elemental selenium and sodium doped indium. The elemental selenium may be ionized to increase monolayer reaction reactivity. The buffer layer is a non-toxic ZnS-O layer.

### CROSS-REFERENCE TO RELATED APPLCATION

This application claims priority under 35 U.S.C. §119(e) to U.S. Provisional patent application No. 61/273,840 filed on Aug. 10, 2009, which is hereby incorporated by reference for all purposes.

### BACKGROUND

1. Field of Invention

The present invention disclosed herein relates generally to the field of photovoltaics, and more specifically to a flexible solar cell coating apparatus and method of manufacturing flexible copper-indium-gallium-diselenide cells.

2. Background

Technological advances leading to improved conversion efficiency and lower manufacturing costs have led to increased interest in and use of thin film photovoltaics. Copper indium gallium diselenide (CIGS) is a commonly used absorption layer in thin film solar cells. CIGS thin film solar cells have achieved excellent conversion efficiency (>19.5%) in laboratory environments.

Currently, most CIGS deposition is done by one of two techniques: co-evaporation or selenization. Co-evaporation involves simultaneously evaporating copper, indium, gallium and selenium. The different melting points of the four elements makes controlling the formation of a stoichimetric compound on a large substrate very difficult. Additionally, film adhesion is very poor when using co-evaporation. Selenization is a two-step process. First, a copper, gallium, and indium precursor is sputtered on to a substrate. Second, selenization occurs by reacting the precursor with toxic H₂Se at 550° C. or above. The H₂Se is difficult to control. Furthermore, the high temperature leads to uneven mixing of the copper, indium, gallium, and selenium and generates lattice defects that reduce the cell's efficiency. Additionally, both techniques require excessive selenium, approximately four times the necessary amount, and do not easily scale up for volume production.

Accordingly, there exists a need for a safer and more efficient manufacturing process of a CIGS thin film solar cell that has the advantages of a complete mixing of the absorption components with a volume production that is easy to scale up.

### SUMMARY

In accordance with the invention, incomplete mixing and inability to easily scale up production are solved by monolayer reactions and a flexible substrate. Rotation of the flexible substrate can limit deposition of absorption components to only enough atoms or molecules to react in a monolayer reaction. In some embodiments, a rotating drum within a flexible solar cell coating apparatus can rotate the flexible substrate. A roll of flexible substrate may be placed on a loading roller. A section of the roll of flexible substrate can advance around a circumference of the rotating drum. As the section rotates, a hybrid process of sputtering and evaporation may deposit absorption components on to the section. The monolayer reaction of absorption components can occur and result in a layer of an absorption film. Deposition can continue until a desired thickness of the absorption film is met. Following completion of deposition, a buffer layer is deposited. After deposition of the buffer layer is complete, the section may be rewound around an exit roller. A new section of the roll of flexible substrate can then advance around the circumference of the rotating drum and undergo deposition.

In particular embodiments of the invention, the absorption film may be a CIGS film. Sodium doped indium can eliminate the need for an alkali-silicate layer. The usage of elemental selenium may render the process safe and non-toxic. Also in particular embodiments, the elemental selenium can be ionized to increase reactivity thereby lowering reaction temperature.

According to an embodiment, there is an apparatus for depositing one or more layers of a flexible solar cell. The apparatus comprises a housing defining a vacuum chamber; a rotating drum disposed within the vacuum chamber and coupled to a bottom of the vacuum chamber; a loading roll configured to advance a section of a substrate around a circumference of the rotating drum; a heater configured to heat the section of the substrate; a plurality of absorption component sputtering sources configured to deposit a plurality of absorption components on a surface of the section of the substrate; an evaporation source configured to vaporize an absorption component for deposition on the surface of the section of the substrate; an isolation baffle configured to prevent contamination of the plurality of absorption component sputtering sources by the evaporation source; a buffer layer sputtering source configured to deposit a buffer layer component on the surface of the section of substrate; and an exit roll configured to take up the section of the substrate from the rotating drum.

According to another embodiment, there is a method of depositing an absorption layer and a buffer layer of a solar cell. The method comprises placing a roll of substrate on a loading roller; advancing a section of the roll around a circumference of a rotating drum; depositing the absorption layer on a surface of the section, wherein the depositing occurs during rotation of the rotating drum; depositing the buffer layer on the absorption layer; and unloading the section of the roll from the rotating drum by winding the section around an exit roller.

These and other embodiments of the present invention are further made apparent, in the remainder of the present document, to those of ordinary skill in the art.

### BRIEF DESCRIPTION OF THE DRAWINGS

In order to more fully describe embodiments of the present invention, reference is made to the accompanying drawings. These drawings are not to be considered limitations in the scope of the invention, but are merely illustrative.

FIG. 1 is a schematic view of a structure of a prior art CIGS cell.

FIG. 2 illustrates a schematic side view of an example flexible solar cell coating apparatus.

FIG. 3 illustrates a schematic top view of an example flexible solar cell coating apparatus.

FIG. 4 illustrates a perspective view of an example of an isolation baffle.

FIGS. 5a, 5b, and 5c illustrate a sectional view of a deposition of a CIGS film on a substrate.

FIG. 6 is a graph illustrating an Auger Electron Spectroscopy (AES) depth profile analysis of an example CIGS film according to an embodiment of the present invention.

FIG. 7 illustrates an X-ray diffraction spectrum of an example CIGS cell according to an embodiment of the present invention.

FIG. 8 is a flow diagram of an example method for depositing a CIGS film and a ZnS—O layer on a flexible substrate.

### DETAILED DESCRIPTION OF SPECIFIC EMBODIMENTS

The description above and below and the drawings of the present document focus on one or more currently preferred embodiments of the present invention and also describe some exemplary optional features and/or alternative embodiments. The description and drawings are for the purpose of illustration and not limitation. Those of ordinary skill in the art would recognize variations, modifications, and alternatives. Such variations, modifications, and alternatives are also within the scope of the present invention. Section titles are terse and are for convenience only.

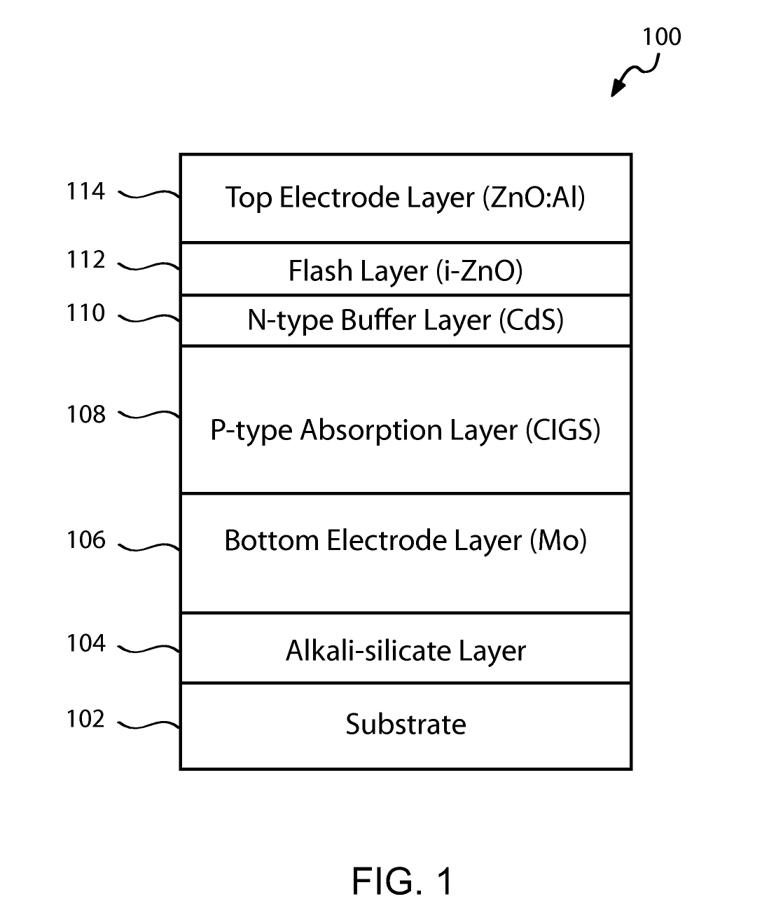

FIG. 1 is a schematic view of a structure of a prior art CIGS cell 100. The prior art CIGS cell has a substrate 102 with multiple layers deposited upon a surface of the substrate 102. Suitable substrate materials may include glass, aluminum, stainless steel, polymers or any similarly flexible metals and plastics. An alkali-silicate layer 104 is deposited on to the substrate 102. Typically, sodium from the alkali-silicate layer 104 penetrates through a bottom electrode layer 106 to an absorption layer 108 and enhances cell efficiency. Next, the bottom electrode layer 106 of molybdenum is sputtered on to the alkali-silicate layer 104. The bottom electrode layer 106 is approximately 1000 nm thick. A p-type absorption layer 108 is deposited on the bottom electrode layer 106. The p-type absorption layer 108 is approximately 2000 nm thick and composed of copper, indium, gallium, and selenium. An n-type buffer layer 110 is deposited on top of the p-type absorption layer 108. The n-type buffer layer 110 is composed of cadmium sulfide. Cadmium sulfide is toxic. A flash layer 112 of zinc oxide is sputtered on to the n-type buffer layer 110. The flash layer 112 of zinc oxide serves as shunt prevention to reduce the impact of pinholes and defects in a CIGS film. Both the n-type buffer layer 110 and the flash layer 112 are approximately 50 nm thick. Finally, a top electrode layer 114 of aluminum doped zinc oxide is sputtered on to the flash layer 112. The top electrode layer 114 is about 800 nm thick.

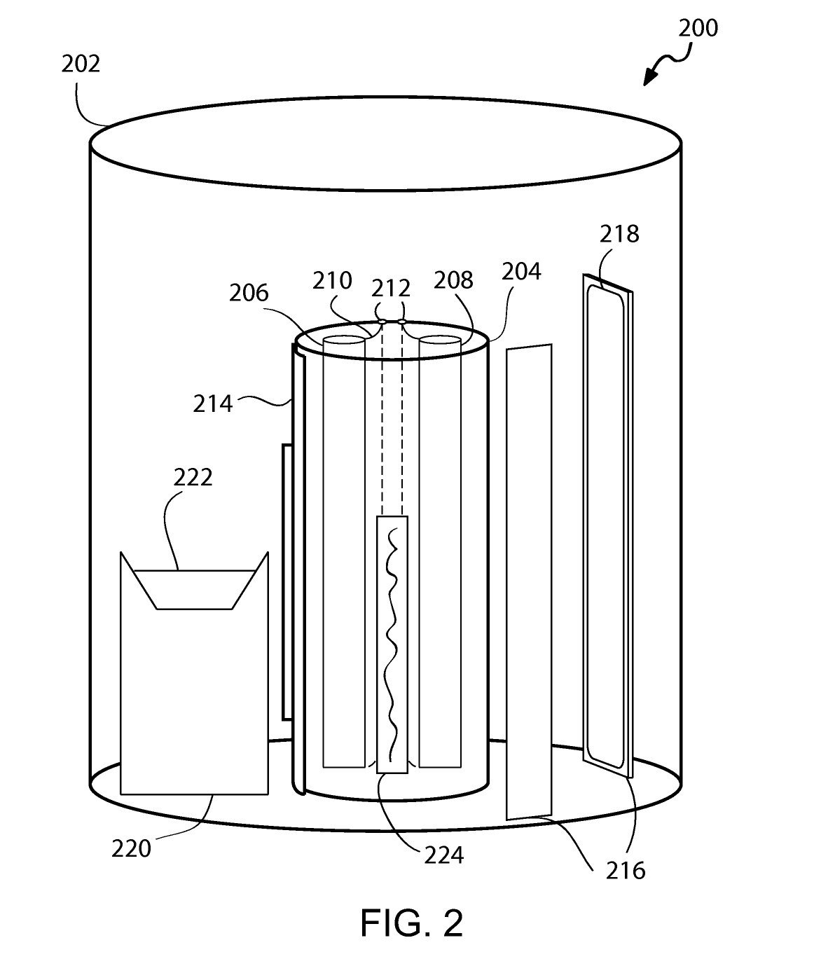

FIG. 2 illustrates a schematic perspective view of an example flexible solar cell coating apparatus 200 according to an embodiment of the present invention. A flexible solar cell coating apparatus may include, but is not limited to, a housing 202, a rotating drum 204, a loading roller 206, an exit roller 208, a heater 224, a plurality of sputtering sources 216, a plurality of sputtering targets 218, at least one evaporation source 220, and an isolation baffle 214.

The housing 202 generally defines a vacuum chamber. In a present embodiment, the housing 202 can define a single, 1.2 m tall, vacuum chamber with a diameter of 1 m. The housing 202 also can be rectangular shaped with three removable doors built on three sides of the vacuum chamber. The housing 202 may be composed of stainless steel or other metals and alloys used for drum coater housings.

The rotating drum 204 is disposed within the vacuum chamber. The rotating drum 204 can be approximately 0.8 m tall and may have a diameter of 0.8 m. The rotating drum 204 may comprise an indexing mechanism 212 to monitor substrate advancement around a circumference of the rotating drum 204. The indexing mechanism 212 may further comprise a sensor. The loading roller 206 and a substrate pulling mechanism may stop advancing a substrate around the rotating drum when the sensor detects the substrate completely covering the circumference of the rotating drum 204. In an embodiment, the rotating drum 204 comprises a top plate and bottom plate (not shown). The top plate of the rotating drum 204 may be directly coupled to a drive shaft, a motor, or other mechanism that actuates drum rotation from the top of the vacuum chamber. Rotation between 60 to 150 RPM can prevent excessive deposition of absorption components upon the substrate. In a present embodiment, the rotating drum 204 rotates at 120 RPM. Deposition of absorption components may be limited to a monolayer of atoms or molecules. The monolayer contains enough atoms or molecules to cover a surface of the substrate in a single layer of atoms or molecules without any excess atoms or molecules stacked upon the single layer.

The loading roller 206 and the exit roller 208 may be disposed within an interior of the rotating drum 204 and coupled to both the top plate and bottom plate of the rotating drum 204. In another embodiment, the rollers 206, 208 are coupled to the top plate. A typical roller may be 80 cm tall and can be made of stainless steel. A stainless steel shaft can be disposed within an interior of the typical roller. The loading roller 206 may be configured to receive a roll of substrate. The loading roller 206 can unwind a section 210 of the roll of substrate and can advance the section 210 around the circumference of the rotating drum 204, such that all around the circumference of the rotating drum 204 the section 210 may be flush against a surface of the rotating drum 204. The exit roller 208 may unload the section 210 from the rotating drum 204 following the deposition process by rewinding the section 210 around the exit roller 208.

The flexible solar cell coating apparatus may have one or more heaters 224 to heat the substrate during sputtering and evaporation. In one embodiment, the heater 224 may be disposed within the interior of the rotating drum 204. The heater 224 is disposed to be still inside the rotating drum such that its power source extends through the bottom plate of the rotating drum 204. The drum 204 is thereby rotatable around the heater 224. In another embodiment, one or more heaters 224 can be disposed outside of the rotating drum 204, coupled to a bottom surface of the vacuum chamber and thereby separate from the rotating top and bottom plates of the rotating drum 204. The heater 224 can be an infrared or a halogen bulb heater typically used and known in the art to heat substrate during deposition processes. The heater 224 can heat the substrate to a temperature between 300 to 550° c.

The flexible solar cell coating apparatus can have a plurality of sputtering sources 216. The plurality of sputtering sources 216 can be disposed within the vacuum chamber between the rotating drum 204 and the housing 202. The plurality of sputtering sources 216 may be coupled to the bottom of the vacuum chamber. The plurality of sputtering sources 216 and the at least one evaporation source 220 may be equally distributed around the circumference of the rotating drum 204. The plurality of sputtering sources 216 may be any sputtering source commonly used for thin film deposition such as magnetrons, ion beam sources, or RF generators.

Each of the plurality of sputtering sources 216 may correspond to one of a plurality of sputtering targets 218. The plurality of sputtering targets 218 can be 10 cm wide and 1 m tall. In a present embodiment, there may be a single Cu—Ga sputtering target and a single sodium doped indium target. The Cu—Ga sputtering target can be 70 to 80% copper and 20 to 30% gallium. The sodium doped indium target may contain 2 to 3% sodium. Doping the indium with sodium may result in lower manufacturing costs by eliminating the need for an alkali-silicate layer. Doping indium with sodium may also be preferred over depositing an extra alkali-silicate layer because sodium is directly introduced to the CIGS layer. The indium can be doped with other alkali elements such as potassium. In another embodiment, there may be multiple Cu-Ga sputtering targets and multiple sodium doped indium targets. For example, the flexible solar cell coating apparatus may have a 70:30 Cu—Ga sputtering target and an 80:20 Cu—Ga sputtering target for grade composition sputtering.

The flexible solar cell coating apparatus can have an evaporation source 220 configured to produce a vapor of an evaporation source material 222. The vapor may condense upon the substrate. The evaporation source 220 may be an evaporator boat, crucible, filament coil, electron beam evaporation source, or the like. In a present embodiment, the evaporation source material 222 may be non-toxic elemental selenium.

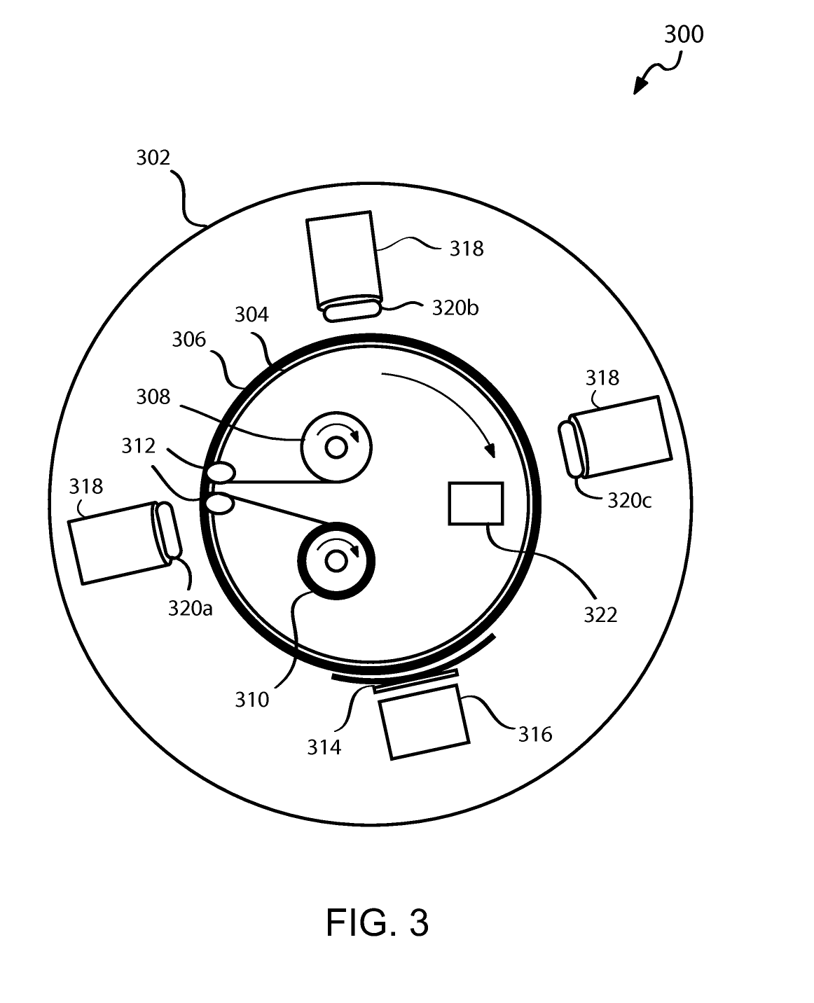

FIG. 3 illustrates a schematic top view of the example flexible solar cell coating apparatus 300. A flexible solar cell coating apparatus may include, but is not limited to, a housing 302, a rotating drum 304, a loading roller 308, an exit roller 310, one or more heaters 322, a plurality of sputtering sources 318, a plurality of sputtering targets 320a-c, at least one evaporation source 316, and an isolation baffle 314. Although FIG. 3 illustrates clockwise rotation, this is not intended to be limiting as the rotating drum 304 may turn counter-clockwise. Reversing positions of the loading roller 308 and the exit roller 310 may allow for counter-clockwise winding and unwinding of a substrate 306.

Although FIG. 3 is illustrated with three sputtering targets, each of the three sputtering targets for a different deposition component, this is not intended to be limiting as the flexible solar cell coating apparatus can have any number and type of sputtering targets necessary for deposition of an absorption film and a buffer layer. In a present embodiment, there may be one Cu-Ga sputtering target 320a, one sodium doped indium sputtering target 320b, and one ZnS sputtering target 320c. In another embodiment, the flexible solar cell coating apparatus comprises multiple sputtering targets for any particular deposition component. For example, the flexible solar cell coating apparatus can have two Cu-Ga sputtering targets. The first may have a copper to gallium ratio of 70:30 and the second may have a copper to gallium ratio of 80:20.

The plurality of sputtering sources 318 and the at least one evaporation source 316 may be equally distributed around the circumference of the rotating drum 304. An example flexible solar cell coating apparatus may have three sputtering sources and one evaporation source, totaling four deposition sources. The four deposition sources can be spaced about the rotating drum 304 such that there is one of the four deposition sources every 90 degrees. Equal distribution helps prevent cross contamination of the deposition sources. In another embodiment, the one or more heaters 322 may be disposed entirely outside of the rotating drum 304, inside the vacuum chamber housing 302, closer to the sputtering sources 318.

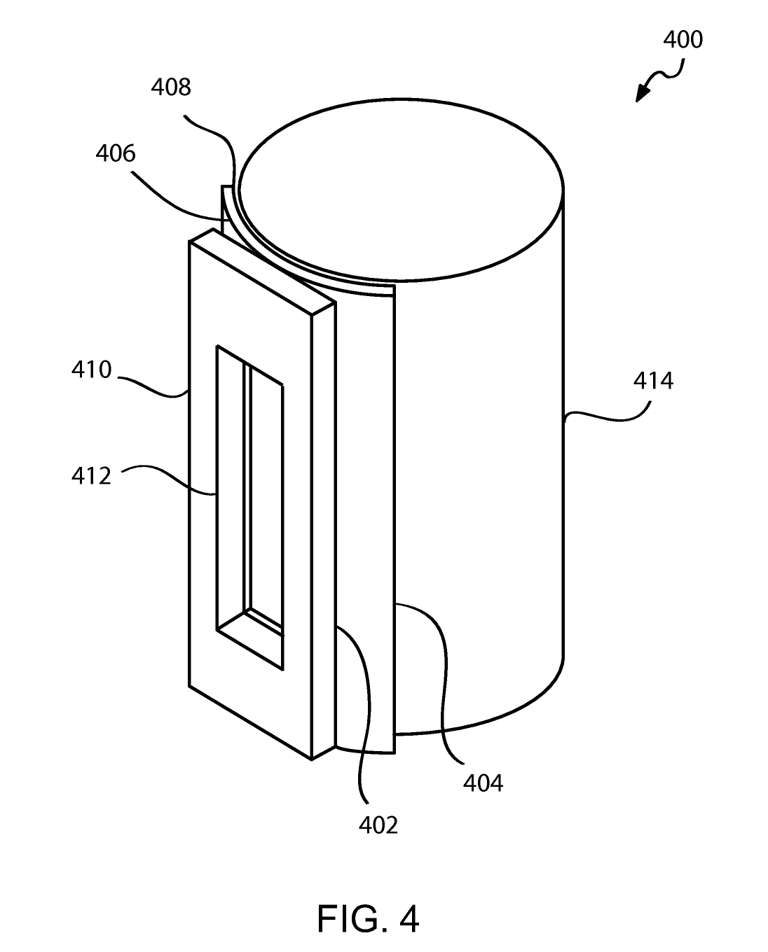

FIG. 4 illustrates a perspective view of an example of an isolation baffle 400 according to an embodiment of the present invention. An isolation baffle 402 may have a curved blade extension 404 and a port member 410. The isolation baffle 402 can prevent contamination of sputtering targets by directing a vapor of an evaporation source material to a particular section of a substrate. The isolation baffle 402 may be composed of stainless steel or other similar metals and metal alloys. The isolation baffle 402 can be disposed within an interior of a vacuum chamber. A bottom end of the isolation baffle can couple to a bottom surface of the vacuum chamber by welding, adhesive, screws, or any other attachment method.

The curved blade extension 404 may match a curvature of a rotating drum 414 and can cover 30 to 90 degrees. A curve interior 408 of the curved blade extension 404 can be positioned to face the rotating drum 414 and may be no further than 5 mm from the rotating drum 414. The port member 410 can be coupled to the curved blade extension 404 at a curve exterior 406. While the port member 410 is illustrated as rectangular, this is not intended to be limiting as the port member 410 may be any shape such as circular, triangular, and the like. A slot 412 can punctuate the port member 410 and the curved blade extension 404. The slot 412 may allow the vapor to pass through the isolation baffle 402 to the substrate.

Although described with reference to a flexible solar cell substrate, the apparatus may be configured for depositing one or more layers on a glass substrate. The typical thickness of the glass substrate may be 1-3 mm, with a width of 30-60 cm, and a length of 60-100 cm. Due to nature of the glass substrate, instead of being rolled inside the rotating drum, the glass substrate would be mounted on an outer surface of the drum for the deposition process.

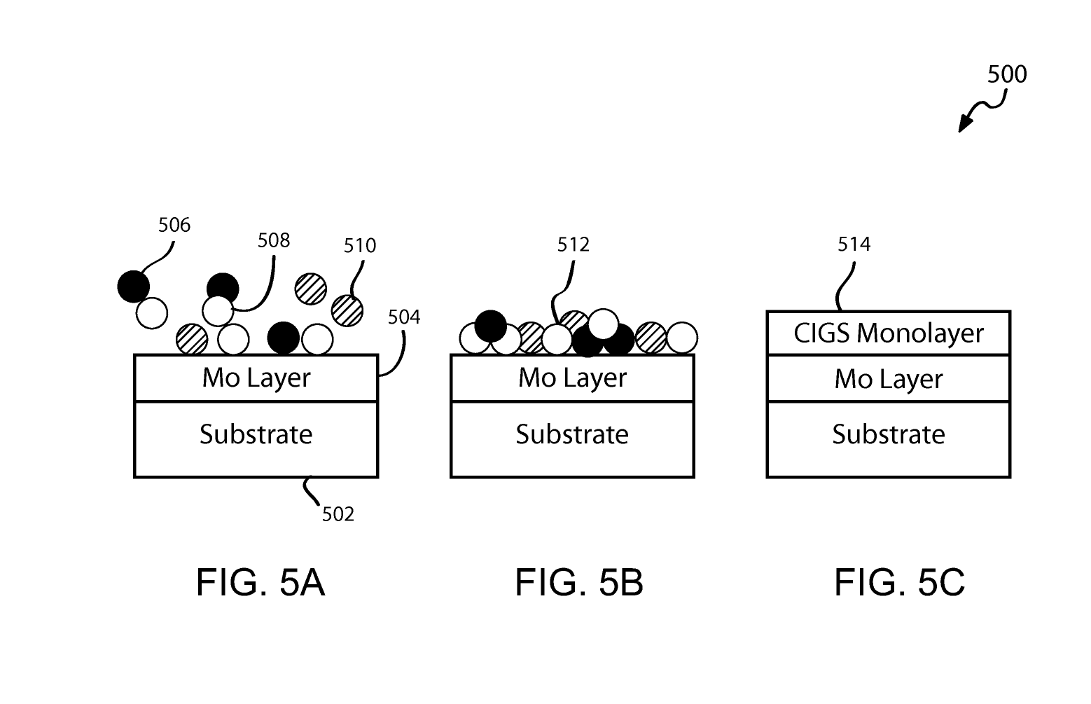

FIGS. 5a, 5b, and 5c illustrate sectional views of a deposition 500 of a CIGS film on a substrate 502 according to an embodiment of the present invention. A plurality of absorption components 506, 508, 510 may deposit upon the substrate 502. The plurality of absorption components 506, 508, 510 can consist of copper, gallium, indium, selenium, and the like. The plurality of absorption components 506, 508, 510 may be simultaneously deposited on the substrate 502 via sputtering and evaporation. In a present embodiment, copper, gallium, and indium may be sputtered while selenium may be evaporated. Adjusting a power source of a sputtering source can control an amount of sputtered absorption component 506, 508 deposited on to the substrate 502. Similarly, adjusting a power source of an evaporation source may control an amount of evaporated absorption component 510 deposited on to the substrate 502. Substrate rotation also can affect the amount of sputtered absorption component 506, 508 and the amount of evaporated absorption component 510 deposited upon the substrate 502.

The plurality of absorption components 506, 508, 510 can react in a monolayer reaction 512. In the present embodiment, the monolayer reaction 512 may form a CIGS layer 514 on the substrate. The monolayer reaction 512 can result in better uniformity and a more consistent bandgap in the CIGS layer 514. In a present embodiment, the CIGS layer 514 may be 10 Å or 1 nm thick. More of the plurality of absorption components 506, 508, 510 can be deposited on top of the CIGS layer 514 to react in another monolayer reaction 512 to form another CIGS layer 514. An aggregate of all the CIGS layers may form a CIGS film. Deposition may continue until a predetermined thickness of the CIGS film is met. In a present embodiment, the predetermined thickness can be 1500 nm. Deposition of a 1500 nm CIGS film may take 10 to 15 minutes. Each rotation of a rotating drum may result in a 1 nm CIGS layer.

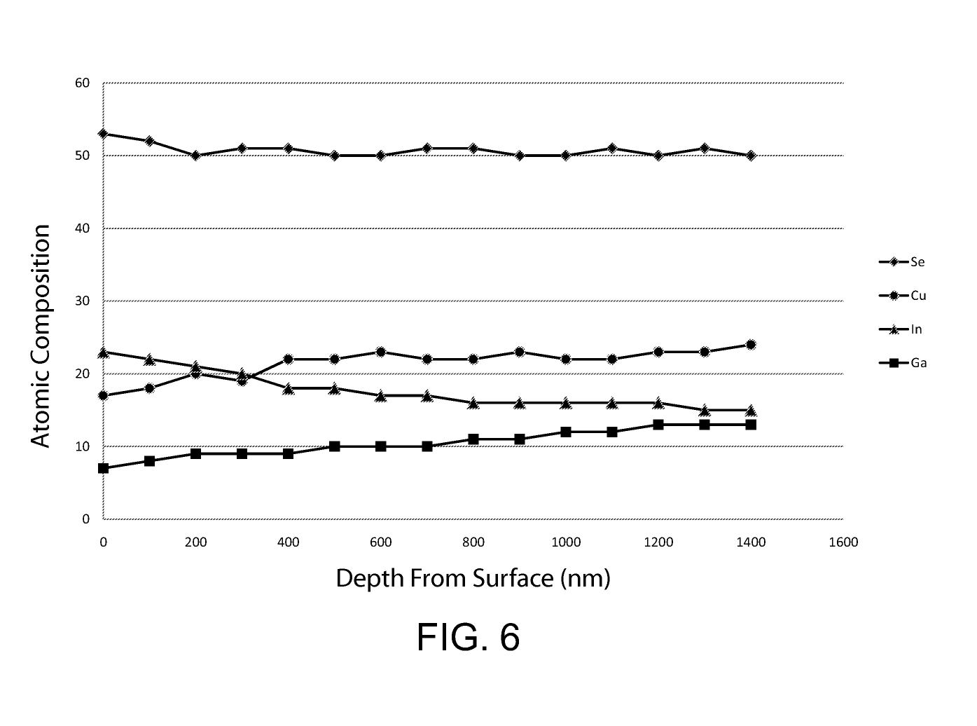

FIG. 6 is a graph illustrating an Auger Electron Spectroscopy (AES) depth profile analysis of an example CIGS film according to an embodiment of the present invention. The AES depth profile analysis proves a technique of the present invention can produce a grade composition in a CIGS film. The AES depth profile analysis can also show the grade composition is consistent across different depths of the CIGS film.

An incoming light can comprise a plurality of wavelengths. Each of the plurality of wavelengths may correspond to an energy. An absorption layer with a graded energy bandgap can completely absorb the energy of the plurality of wavelengths of the incoming light. In a present embodiment, the absorption layer can be the CIGS film. An optimum energy bandgap for the CIGS film can occur between 1.3 to 1.5 eV.

The optimum energy bandgap may result from the grade composition of a plurality of absorption components. In one embodiment, power adjustments during deposition of the plurality of absorption components may produce the grade composition. For example, decreasing power to a Cu-Ga sputtering source and increasing power to a sodium doped indium sputtering source may produce increasing amounts of Cu and Ga and decreasing amounts of indium from a top to a bottom of the CIGS film. In another embodiment, usage of a plurality of sputtering targets of different ratios may produce the grade composition. For example, power can be applied at different times during film deposition to a 70:30 Cu-Ga sputtering target and an 80:20 Cu-Ga sputtering target to obtain the grade composition of Cu and Ga.

An X-axis of the AES depth profile analysis is a depth from a surface of the CIGS film in nanometers. A Y-axis of the AES depth profile analysis is an atomic composition of the plurality of absorption components. The AES depth profile analysis can show the increasing amounts of Cu and Ga in the CIGS film. The AES depth profile analysis may also show a film ratio of Cu to Ga can remain constant across different depths as both Cu and Ga increase in the CIGS film. The film ratio of Cu to Ga may stay constant because Cu and Ga are sputtered from a same sputtering target with a constant target ratio of Cu to Ga. The AES depth profile may also show the decreasing amounts of indium, consistent with the increasing amounts of Cu and Ga, across different depths of the CIGS film. The AES depth profile analysis also can show Se content remains constant throughout the CIGS film.

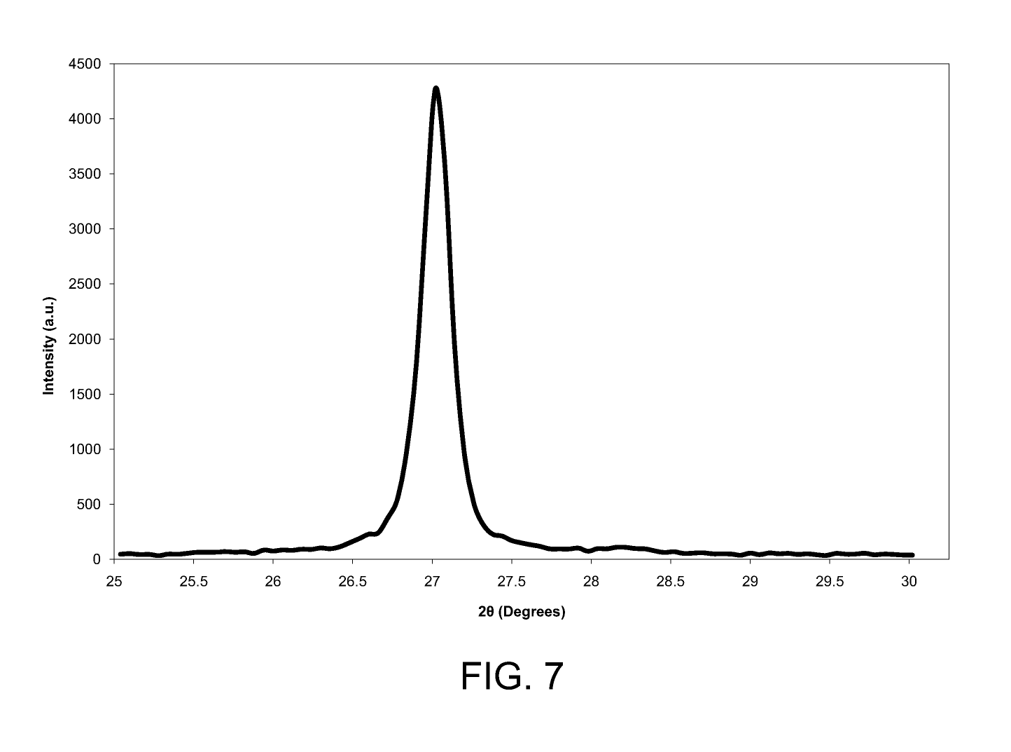

FIG. 7 illustrates an X-ray diffraction spectrum of an example CIGS cell according to an embodiment of the present invention. The X-ray diffraction (XRD) spectrum can prove the example CIGS cell has a chalcopyrite structure. The chalcopyrite structure can be an identifying characteristic of all CIGS cells.

Production of a typical CIGS cell may require high temperature, at least 500° c., to produce the chalcopyrite structure. The chalcopyrite structure can cause diffraction at the (112) plane that corresponds to a sharp peak at approximately 27° on an XRD spectrum of the typical CIGS cell.

The example CIGS cell may be prepared using monolayer reactions to deposit a CIGS film on to a substrate at approximately 350° c. An X-axis of the XRD spectrum is an angle of a diffracted beam from an incident beam in degrees, or 2θ. A Y-axis of the XRD spectrum is an intensity of a reflected beam in a.u. A peak of the XRD spectrum may appear centered around 27°. The peak can indicate the example CIGS cell prepared at low temperature using monolayer reactions can possess the chalcopyrite structure.

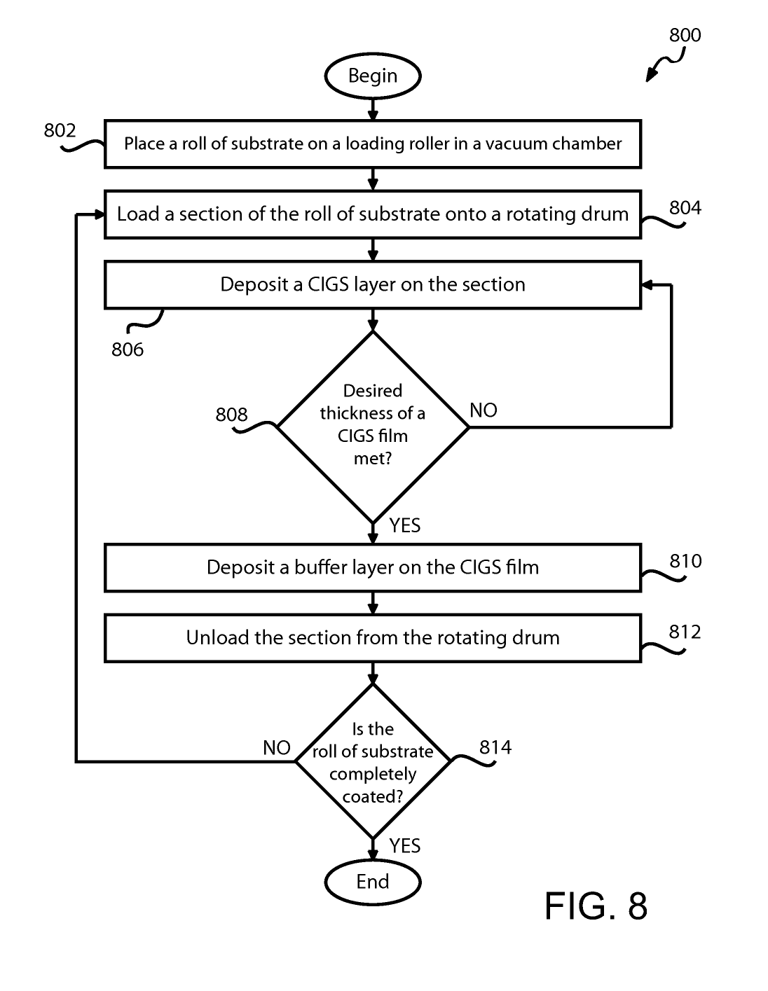

FIG. 8 is a flow diagram of an example method for depositing a CIGS film and a ZnS—O layer on a flexible substrate 800. The method for depositing may begin by placing 802 a roll of substrate on a loading roller in a vacuum chamber. In one embodiment, the substrate may be 0.1 mm thick and can be pre-coated with a back contact layer of molybdenum or any other metal or compound used for back electrical contact layers. Suitable substrate materials may include aluminum, stainless steel, polymers or other such flexible metals and plastics. In another embodiment, the substrate may be a glass substrate. The typical thickness of the glass substrate may be 1-3 mm, with a width of 30-60 cm, and a length of 60-100 cm. The glass substrate can be mounted to an outer surface of a rotating drum. The rotating drum may be capable of receiving multiple glass substrates.

A section of the roll of substrate may then be loaded 804 on to the rotating drum. The loading 804 may entail the loading roller unwinding the section from the roll of substrate and advancing the section around the circumference of the rotating drum. The section may be flush against a surface of the rotating drum. An indexing mechanism of the rotating drum controls a length of the section unwound from the roll of substrate.

After the section is loaded 804, a CIGS layer can be deposited 806 on the section. Deposition 806 of the CIGS layer may occur under vacuum as the rotating drum rotates and the heater heats the section. A vacuum pump may remove gas molecules from the vacuum chamber to leave a vacuum within the vacuum chamber. The rotating drum can rotate using a motor or any other mechanism capable of actuating rotational movement. The rotating drum can rotate at 60 to 150 RPM during deposition 806 of the CIGS layer. The heater can be an infrared or a halogen bulb heater typically used and known in the art to heat substrate during deposition processes. In a present embodiment, the heater may heat the substrate to a temperature between 300 to 550° c.

Deposition 806 of the CIGS layer can be a hybrid process comprising simultaneous sputtering and evaporation of a plurality of absorption components. For example, Cu-Ga and sodium doped indium targets are sputtered while elemental selenium is evaporated on to the section. Each rotation of the rotating drum may result in the deposition of a couple atoms or molecules of the plurality of absorption components. The couple atoms or molecules of the plurality of absorption components can react in a monolayer reaction. The monolayer reaction may result in the CIGS layer. The CIGS layer can be 10 Å thick.

Sputtering may utilize a sputtering gas and a plurality of sputtering sources. In a present embodiment, sputtering is performed with an argon gas. Other possible sputtering gases include krypton, xenon, neon, and similarly inert gases. Any sputtering sources commonly used for thin film deposition such as magnetrons, ion beam sources, RF generators, or the like may be used for sputtering.

For each sputtering source, there may be a sputtering target. In a present embodiment, there may be a single Cu-Ga sputtering target and a single sodium doped indium target. In another embodiment, there may be multiple Cu-Ga sputtering targets and multiple sodium doped indium targets. The targets can be 10 cm wide and 1 m tall.

Different absorption components may be combined to form the sputtering target. For example, copper and gallium powder can be pressed together to form a Cu-Ga sputtering target. Cu-Ga sputtering targets prepared in this manner can have varying copper to gallium ratios, such as, but not limited to 80:20 and 70:30. Although the preceding was described in reference to copper and gallium, this is not intended to be limiting as sputtering targets for other absorption components can be prepared and utilized in the same manner.

Evaporation comprises vaporizing an evaporation source material with an evaporation source and condensing a vapor of the evaporation source material on the substrate. In a present embodiment, the evaporation source material may be non-toxic elemental selenium. The evaporation source can be an evaporator boat, crucible, filament coil, electron beam evaporation source, or the like. The vapor of the evaporation source material may also be ionized prior to condensation on the substrate to increase reactivity. Increased reactivity may result in a need for less evaporation source material, and lower substrate temperatures. In a present embodiment, selenium vapor can be ionized using an ionization discharger.

A determination 808 of whether a desired thickness of the CIGS film on the substrate is met. The determination 808 may comprise a deposition of each of the plurality of absorption components for a constant period of time. A thickness of the deposition of each of the plurality of absorption components may be measured. A deposition rate of each of the plurality of absorption components can be calculated from the thickness and the constant period of time. The deposition rate along with deposition source power settings may then be used to determine 808 whether a desired thickness of the CIGS film on the substrate is met.

If it is determined 808 the desired thickness is not met, the step of depositing 806 a CIGS layer may be repeated. However, the sputtering and evaporation of the plurality of absorption components may now occur on an uppermost CIGS layer. If it is determined 808 the desired thickness is met, a buffer layer may be deposited 810 on the uppermost CIGS layer. In a present embodiment, the buffer layer can be non-toxic ZnS-O. The buffer layer can be deposited by sputtering ZnS in a sputtering gas of 80 to 90% argon and 10 to 20% oxygen.

After the buffer layer is deposited 810, the section now coated with the CIGS film and the buffer layer may be unloaded 812 from the rotating drum. The section is rewound around an exit roller.

A determination 814 of whether the roll of substrate is completely coated. If it is determined 814 the roll of substrate is not completely coated, the method may start over with a new section of the roll of substrate loaded 804 on to the rotating drum. If it is determined 814 the roll of substrate is completely coated, the vacuum can be broken. The roll of substrate may be removed. Additionally, a new roll of substrate can be placed 802 on the loading roller.

Throughout the description and drawings, example embodiments are given with reference to specific configurations. It will be appreciated by those of ordinary skill in the art that the present invention can be embodied in other specific forms. Those of ordinary skill in the art would be able to practice such other embodiments without undue experimentation. The scope of the present invention, for the purpose of the present patent document, is not limited merely to the specific example embodiments or alternatives of the foregoing description.

What is claimed is:

1. An apparatus for depositing one or more layers of a flexible solar cell, the apparatus comprising:
a housing defining a vacuum chamber;
a rotating drum disposed within the vacuum chamber and coupled to a top of the vacuum chamber;
a loading roll configured to advance a section of a substrate around a circumference of the rotating drum;
a heater configured to heat the section of the substrate;
a plurality of absorption component sputtering sources configured to deposit a plurality of absorption components on a surface of the section of the substrate;
an evaporation source configured to vaporize an absorption component for deposition on the surface of the section of the substrate;
an isolation baffle configured to prevent contamination of the plurality of absorption component sputtering sources by the evaporation source;
a buffer layer sputtering source configured to deposit a buffer layer component on the surface of the section of substrate; and
an exit roll configured to take up the section of the substrate from the rotating drum.

2. The apparatus according to claim 1, wherein the plurality of absorption components comprises copper, gallium, selenium and sodium doped indium.

3. The apparatus according to claim 2, wherein one of the sputtering sources is a sodium doped indium source having two to three percent sodium.

4. The apparatus according to claim 1, wherein each of the plurality of sputtering sources and the evaporation source is evenly distributed around an outer circumference of the rotating drum.

5. The apparatus according to claim 1, wherein the buffer layer component comprises ZnS—O.

6. The apparatus according to claim 1, wherein the isolation baffle comprises
a curved blade extension having an inner surface and an outer surface, the inner surface matching a curvature of the rotating drum and
a port member coupled to the outer surface of the curved blade extension.

7. The apparatus according to claim 1, wherein the rotating drum is configured to receive a plurality of glass substrates.

8. A method of depositing an absorption layer and a buffer layer of a solar cell, comprising:
placing a roll of substrate on a loading roller inside a rotating drum;
advancing a section of the roll around a circumference of the rotating drum;
depositing the absorption layer on a surface of the section, wherein the depositing occurs during rotation of the rotating drum;
depositing the buffer layer on the absorption layer; and
unloading the section of the roll from the rotating drum by winding the section around an exit roller.

9. The method of claim 8, wherein each of the steps are provided within a vacuum chamber.

10. The method of claim 8, wherein the step of depositing the absorption layer on a surface of the section comprises simultaneous sputtering and evaporation of a plurality of absorption components.

11. The method of claim 8, wherein the step of depositing the absorption layer on the surface of the section is repeated to reach a predetermined thickness of the absorption layer.

12. A method of depositing a CIGS layer and a ZnS-O layer, comprising:
placing a roll of flexible substrate on a loading roller;
advancing a section of the roll of flexible substrate around a circumference of a rotating drum;
forming a CIGS layer on to a surface of the section, the forming comprising:
rotating the rotating drum;
sputtering a plurality of copper, gallium, and sodium doped indium atoms on to the surface of the section;
evaporating an elemental selenium material to deposit a plurality of selenium atoms on the surface of the section;
reacting the plurality of copper, gallium, and sodium doped indium atoms with the plurality of selenium atoms in a monolayer reaction;
wherein the forming a CIGS layer is repeated until a predetermined thickness of a CIGS film is met;
depositing a ZnS-O layer on top of the CIGS film; and
unloading the section of the roll from the rotating drum by winding the section around an exit roller.

13. The method of claim 12, wherein the depositing of a plurality of selenium atoms further comprises ionizing the plurality of selenium atoms to increase reaction rate.

14. The method of claim 13, wherein the ionizing is performed by an ionization discharger.

15. A flexible CIGS cell made by the method according to claim 12.
